(19) United States
(12) Patent Application Publication
(10) Pub. No.: US 2024/0196693 A1
(43) Pub. Date: Jun. 13, 2024

(54) DISPLAY DEVICE AND MOTHER SUBSTRATE FOR DISPLAY DEVICE

(71) Applicant: Japan Display Inc.,, Tokyo (JP)

(72) Inventors: Sho YANAGISAWA, Tokyo (JP); Ryota TAKASAKI, Tokyo (JP); Naoya IWAHASHI, Tokyo (JP); Hiroshi TABATAKE, Tokyo (JP); Kazuyuki HARADA, Tokyo (JP)

(73) Assignee: Japan Display Inc.,, Tokyo (JP)

(21) Appl. No.: 18/509,351

(22) Filed: Nov. 15, 2023

(30) Foreign Application Priority Data
Dec. 9, 2022 (JP) 2022-197273

(51) Int. Cl. H10K 59/80

(52) U.S. Cl. CPC H10K 59/80515; H10K 59/80521

(57) ABSTRACT

According to one embodiment, a display device includes an organic insulating layer, a lower electrode, a rib, a partition including a lower portion and an upper portion protruding from a side surface of the lower portion, an organic layer provided on the lower electrode, an upper electrode, and a terminal electrode. The organic insulating layer comprises a first aperture from which the terminal electrode is exposed. The rib includes a second aperture from which the terminal electrode is exposed. The second aperture is larger than the first aperture in plan view. The organic insulating layer exposed from the rib between the first aperture and the second aperture has a frame-like shape.

### CROSS-REFERENCE TO RELATED APPLICATIONS

This application is based upon and claims the benefit of priority from Japanese Patent Application No. 2022-197273, filed Dec. 9, 2022, the entire contents of which are incorporated herein by reference.

### FIELD

Embodiments described herein relate generally to a display device and a mother substrate for a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a plan view showing a configuration example of a pad PD.

FIG. 12 is a cross-sectional view of the pad PD along the a-b line of FIG. 11.

FIG. 13 is a cross-sectional view for explaining the state in which an evaporated film DF is formed in the pad PD shown in FIG. 12.

FIG. 14 is a cross-sectional view for explaining the state in which the evaporated film DF is formed in the pad PD according to a comparative example.

FIG. 15 is a cross-sectional view showing another configuration example of the pad PD along the a-b line of FIG. 11.

FIG. 16 is a cross-sectional view for explaining the state in which the evaporated film DF is formed in the pad PD shown in FIG. 15.

FIG. 17 is a plan view showing an example of a mother substrate 100 for a display device.

FIG. 18 is a plan view showing an example of the alignment mark AM shown in FIG. 17.

FIG. 19 is a cross-sectional view showing a configuration example of a mark area MKA along the C-D line of FIG. 18.

FIG. 20 is a cross-sectional view showing another configuration example of the mark area MKA along the C-D line of FIG. 18.

FIG. 21 is a cross-sectional view showing another configuration example of the mark area MKA along the C-D line of FIG. 18.

FIG. 22 is a cross-sectional view showing another configuration example of the mark area MKA along the C-D line of FIG. 18.

FIG. 23 is a cross-sectional view showing another configuration example of the mark area MKA along the C-D line of FIG. 18.

FIG. 24 is a cross-sectional view showing another configuration example of the mark area MKA along the C-D line of FIG. 18.

FIG. 25 is a cross-sectional view showing another configuration example of the mark area MKA along the C-D line of FIG. 18.

### DETAILED DESCRIPTION

Embodiments described herein aim to provide a display device and a mother substrate for a display device such that the reduction in reliability can be prevented.

In general, according to one embodiment, a display device comprises a substrate, an organic insulating layer provided over a display area which displays an image and a surrounding area outside the display area above the substrate, a lower electrode provided on the organic insulating layer in the display area, a rib formed of an inorganic insulating material and overlapping a peripheral portion of the lower electrode, a partition which comprises a lower portion provided on the rib and formed of a conductive material, and an upper portion provided on the lower portion and protruding from a side surface of the lower portion, an organic layer provided on the lower electrode and including a light emitting layer, an upper electrode which covers the organic layer and is in contact with the lower portion of the partition, and a terminal electrode provided in the surrounding area. The organic insulating layer comprises a first aperture from which the terminal electrode is exposed. The rib extends to the surrounding area and comprises a second aperture from which the terminal electrode is exposed. The second aperture is larger than the first aperture in plan view. The organic insulating layer exposed from the rib between the first aperture and the second aperture has a frame-like shape.

According to another embodiment, a mother substrate for a display device comprises a substrate, a plurality of panel portions provided above the substrate, and an alignment mark provided outside the panel portions above the substrate. Each of the panel portions comprises an organic insulating layer provided over a display area which displays an image and a surrounding area outside the display area, a lower electrode provided on the organic insulating layer in the display area, a rib formed of an inorganic insulating material and overlapping a peripheral portion of the lower electrode, a partition which comprises a lower portion provided on the rib and formed a conductive material, and an upper portion provided on the lower portion and protruding from a side surface of the lower portion, an organic layer provided on the lower electrode and including a light emitting layer, an upper electrode which covers the organic layer and is in contact with the lower portion of the partition, and a terminal electrode provided in the surrounding area. A mark area in which the alignment mark is provided comprises a top layer formed of a material different from the organic insulating layer.

According to yet another embodiment, a display device comprises a substrate, an organic insulating layer provided over a display area which displays an image and a surrounding area outside the display area above the substrate, a lower electrode provided on the organic insulating layer in the display area, a rib formed of an inorganic insulating material and overlapping a peripheral portion of the lower electrode, a partition which comprises a lower portion provided on the rib and formed of a conductive material, and an upper portion provided on the lower portion and protruding from a side surface of the lower portion, an organic layer provided on the lower electrode and including a light emitting layer, an upper electrode which covers the organic layer and is in contact with the lower portion of the partition, and a terminal electrode provided in the surrounding area. The organic insulating layer comprises a first aperture from which the terminal electrode is exposed and a recess portion located outside the first aperture. The rib extends to the surrounding area and comprises a second aperture from which the terminal electrode is exposed. A peripheral portion along the second aperture of the rib overlaps the recess portion and is spaced apart from the organic insulating layer.

The embodiments can provide a display device and a mother substrate for a display device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

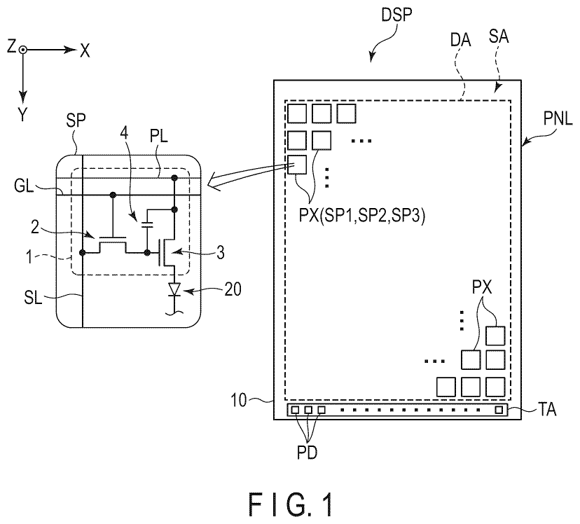

FIG. 1 is a diagram showing a configuration example of a display device DSP.

The display device DSP comprises a display panel PNL comprising a display area DA which displays an image and a surrounding area SA located outside the display area DA on an insulating substrate 10. The substrate 10 may be glass or a resinous film having flexibility.

In the present embodiment, the substrate 10 is rectangular in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a terminal area TA for connecting an IC chip and a flexible printed circuit. The terminal area TA comprises a plurality of pads (terminals) PD. The pads PD are connected to the terminal of the IC chip and the terminal of the flexible printed circuit.

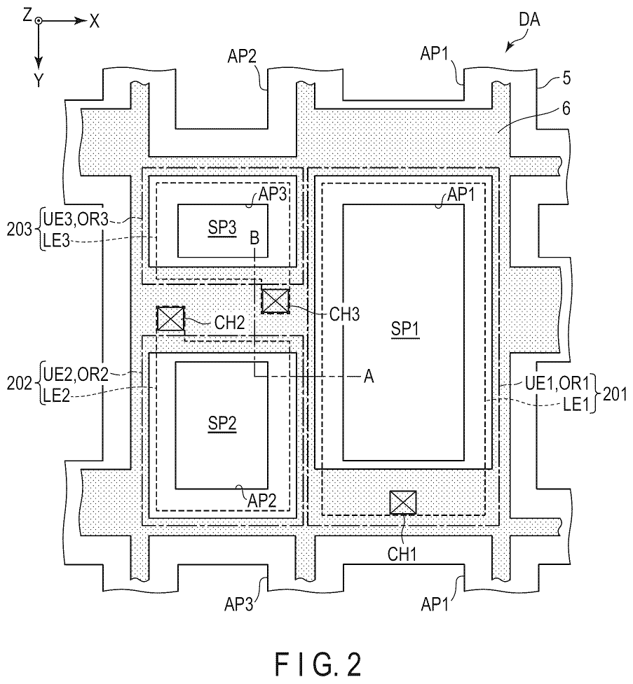

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 in plan view. The partition 6 is formed into a grating shape surrounding the apertures AP1, AP2 and AP3. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shapes of the lower electrodes, organic layers or upper electrodes shown in the figure do not necessarily reflect the accurate shapes.

The peripheral portion of each of the lower electrodes LE1, LE2 and LE3, the peripheral portion of each of the organic layers OR1, OR2 and OR3 and the peripheral portion of each of the upper electrodes UE1, UE2 and UE3 overlap the rib 5 in plan view.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

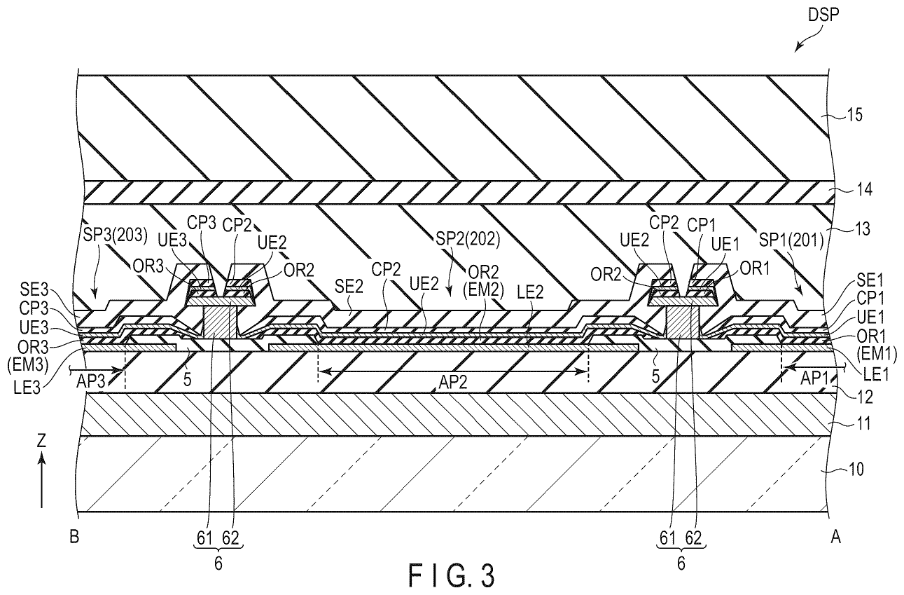

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The rib 5 is provided on the insulating layer 12 and the lower electrodes LE1, LE2 and LE3. The aperture AP1 of the rib 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the rib 5. Between, of the lower electrodes LE1, LE2 and LE3, the lower electrodes which are adjacent to each other, the insulating layer 12 is covered with the rib 5. The lower electrodes LE1, LE2 and LE3 are connected to the pixel circuits 1 of subpixels SP1, SP2 and SP3, respectively, through the contact holes provided in the insulating layer 12.

The partition 6 includes a conductive lower portion (stem) 61 provided on the rib 5 and an upper portion (hat) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the rib 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the rib 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the rib 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, the organic layer OR1, the upper electrode UE1 and the cap layer CP1 are partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, the organic layer OR2, the upper electrode UE2 and the cap layer CP2 are partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, the organic layer OR3, the upper electrode UE3 and the cap layer CP3 are partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the rib 5, the sealing layers SE1, SE2 and SE3 and the sealing layer 14 is formed of, for example, an inorganic insulating material such as silicon nitride (SiNx). Each of the rib 5, the sealing layers SE1, SE2 and SE3 and the sealing layer 14 may be formed of another inorganic insulating material such as silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. Both the lower portion 61 and the upper portion 62 of the partition 6 may be formed of conductive materials.

As described in detail later, each of the lower electrodes LE1, LE2 and LE3 is a multilayer body comprising transparent electrodes and a metal electrode.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

The circuit layer 11, insulating layer 12 and rib 5 shown in FIG. 3 are provided over the display area DA and the surrounding area SA.

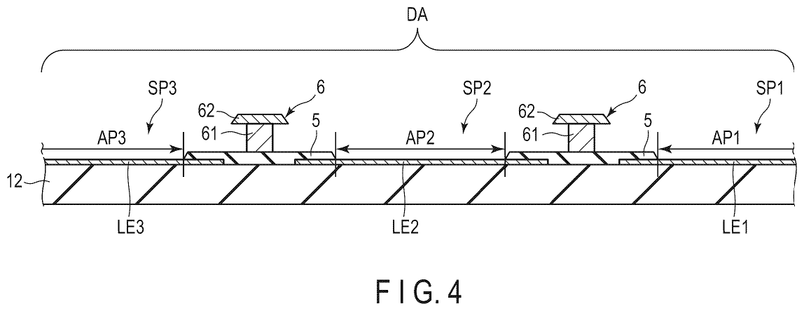

Now, this specification explains the manufacturing method of the display device DSP with reference to FIG. 4 to FIG. 10. In FIG. 4 to FIG. 10, the illustration of the lower side of the insulating layer 12 is omitted.

First, as shown in FIG. 4, after the lower electrodes LE1, LE2 and LE3 are formed on the insulating layer 12, the rib 5 comprising the apertures AP1, AP2 and AP3 and the partition 6 comprising the lower portion 61 and the upper portion 62 are formed. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3.

It should be noted that the partition 6 comprising the lower portion 61 and the upper portion 62 may be formed after the formation of the rib 5 comprising the apertures AP1, AP2 and AP3. Alternatively, the apertures AP1, AP2 and AP3 may be formed after the formation of the partition 6.

Subsequently, the display element 201 is formed.

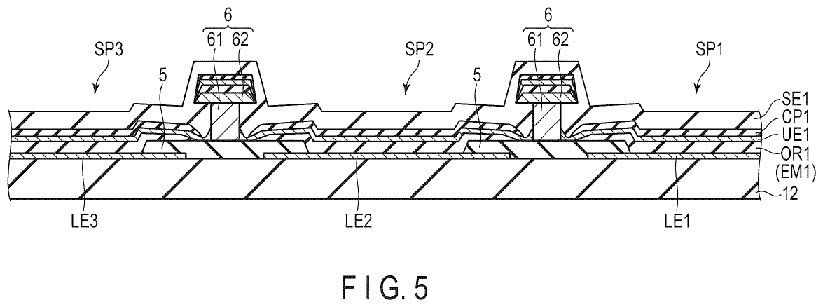

First, as shown in FIG. 5, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series.

Subsequently, the upper electrode UE1 is formed by depositing a mixture of magnesium and silver on the organic layer OR1. The upper electrode UE1 covers the organic layer OR1 and is in contact with the lower portion 61.

Subsequently, the cap layer CP1 is formed by depositing a high-refractive material and a low-refractive material on the upper electrode UE1.

Subsequently, the sealing layer SE1 is formed so as to continuously cover the cap layer CP1 and the partition 6.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

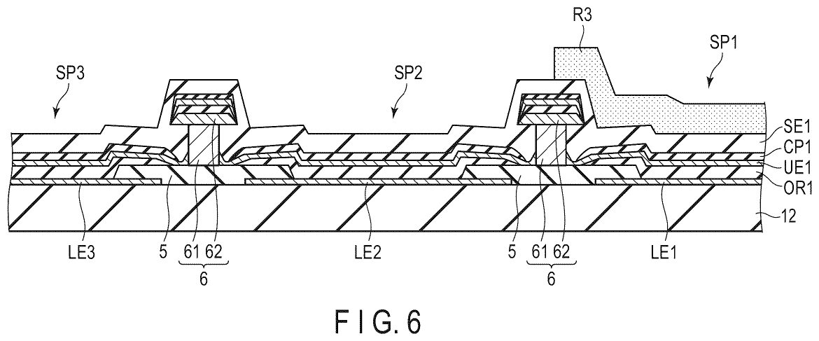

Subsequently, as shown in FIG. 6, a resist R3 having a predetermined shape is formed on the sealing layer SE1. The resist R3 overlaps subpixel SP1 and part of the partition 6 around subpixel SP1.

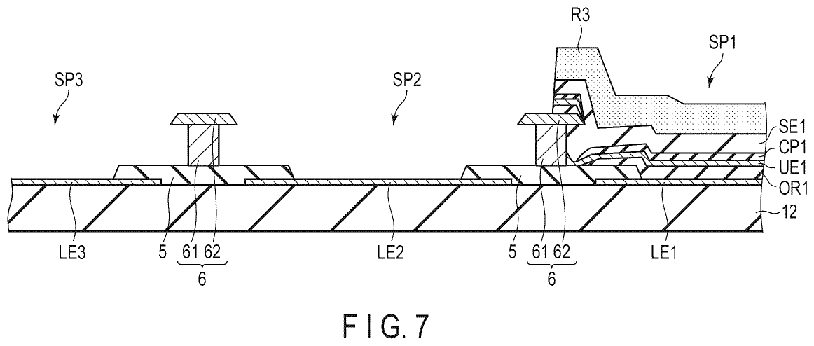

Subsequently, as shown in FIG. 7, the sealing layer SE1, cap layer CP1, upper electrode UE1 and organic layer OR1 exposed from the resist R3 are removed in series by etching using the resist R3 as a mask. In this manner, the lower electrode LE2 of subpixel SP2 and the lower electrode LE3 of subpixel SP3 are exposed.

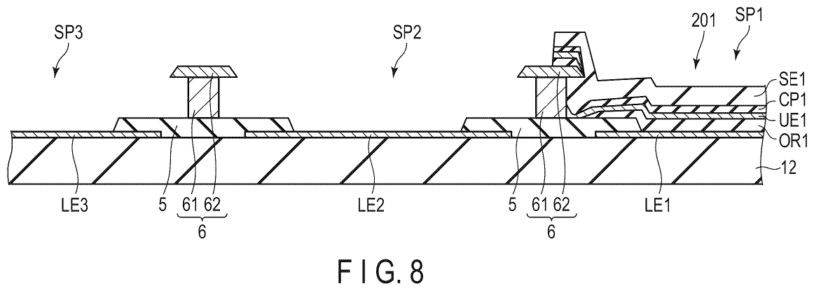

Subsequently, as shown in FIG. 8, the resist R3 is removed. By this process, the display element 201 is formed in subpixel SP1.

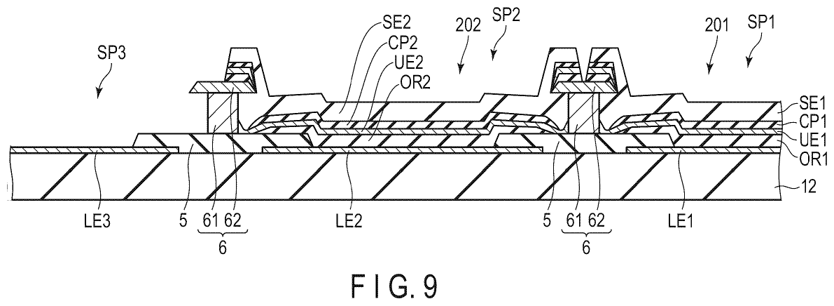

Subsequently, as shown in FIG. 9, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

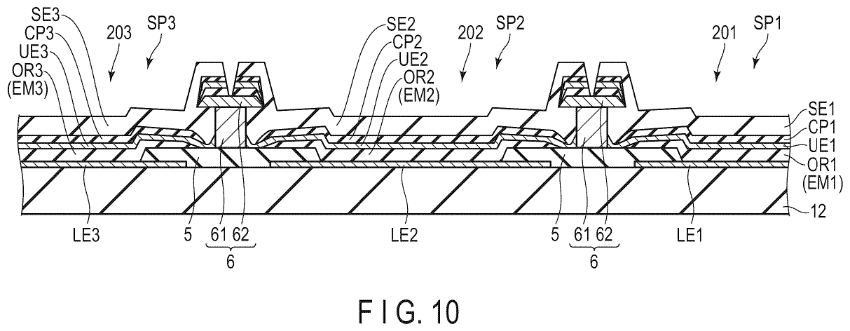

Subsequently, as shown in FIG. 10, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains the pad PD of the surrounding area SA.

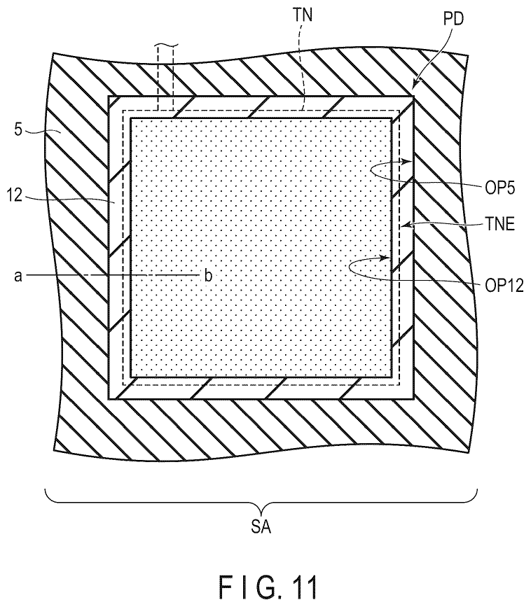

FIG. 11 is a plan view showing a configuration example of the pad PD.

The pad PD comprises a terminal electrode TN.

The insulating layer 12 and the rib 5 are provided in the surrounding area SA in addition to the display area DA. The insulating layer 12 comprises an aperture OP12 from which the terminal electrode TN is exposed. The rib 5 comprises an aperture OP5 from which the terminal electrode TN is exposed. The aperture OP5 is larger than the aperture OP12 in plan view. In addition, the whole circumference of the edge which defines the aperture OP12 is located inside the aperture OP5. Thus, the insulating layer 12 is partly exposed from the rib 5. The insulating layer 12 exposed from the rib 5 between the aperture OP12 and the aperture OP5 has a frame-like shape as shown by hatch lines in the figure.

The peripheral portion of the terminal electrode TN is covered with the insulating layer 12 and does not overlap the rib 5. Thus, the edge TNE of the terminal electrode TN is located outside the aperture OP12 and is located inside the aperture OP5 in plan view.

In the embodiment, for example, the aperture OP12 corresponds to a first aperture, and the aperture OP5 corresponds to a second aperture.

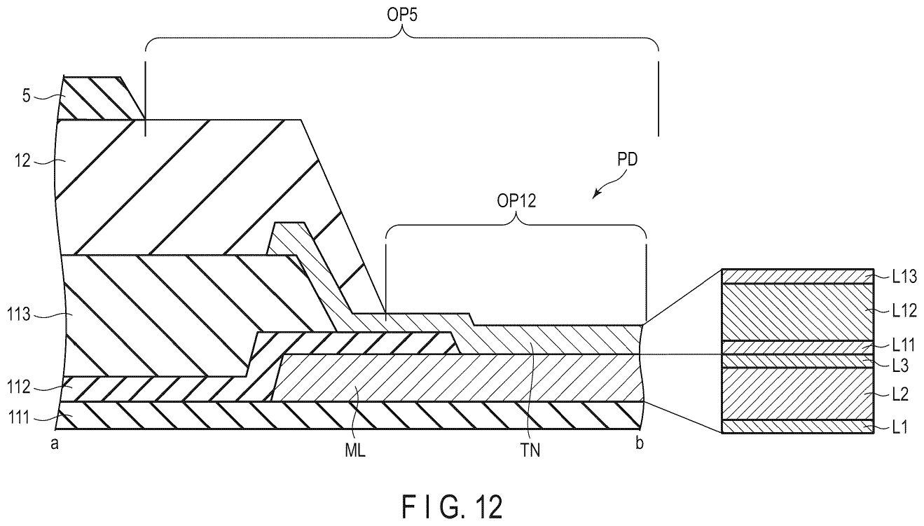

FIG. 12 is a cross-sectional view of the pad PD along the a-b line of FIG. 11.

An insulating layer 111, an insulating layer 112 and an insulating layer 113 are insulating layers included in in the circuit layer 11 shown in FIG. 3. A metal layer ML and the terminal electrode TN are conductive layers included in the circuit layer 11 shown in FIG. 3.

Each of the rib 5, the insulating layer 111 and the insulating layer 112 is an inorganic insulating layer formed of, for example, silicon nitride, silicon oxide or silicon oxynitride.

Each of the insulating layer 113 and the insulating layer 12 is an organic insulating layer formed of polyimide.

The metal layer ML is provided on the insulating layer 111. The metal layer ML is a multilayer body comprising a plurality of thin films formed of metal materials which are different from each other. For example, the metal layer ML comprises a titanium-based thin film L1, an aluminum-based thin film L2 located on the thin film L1 and a titanium-based thin film L3 located on the thin film L2. The thin films L1 and L3 may be molybdenum-based thin films.

The insulating layer 112 is provided on the insulating layer 111 and covers the peripheral portion of the metal layer ML. The insulating layer 113 is provided on the insulating layer 112.

The terminal electrode TN covers the metal layer ML exposed from the insulating layer 112. The peripheral portion of the terminal electrode TN is located on the insulating layer 112 and the insulating layer 113.

The terminal electrode TN is a multilayer body comprising a plurality of thin films formed of metal materials which are different from each other. For example, the terminal electrode TN comprises a titanium-based thin film L1l, an aluminum-based thin film L12 located on the thin film L1l and a titanium-based thin film L13 located on the thin film L12. The thin films L1l and L13 may be molybdenum-based thin films. The thin film L11 is in contact with the thin film L3 of the metal layer ML.

The insulating layer 12 is provided on the insulating layer 113 and covers the peripheral portion of the terminal electrode TN. In the aperture OP12 of the insulating layer 12, the terminal electrode TN (or the thin film L3) is exposed. The rib 5 is provided on the insulating layer 12. In the aperture OP5 of the rib 5, the terminal electrode TN is exposed. The insulating layer 12 is exposed from the rib 5 between the aperture OP5 and the aperture OP12.

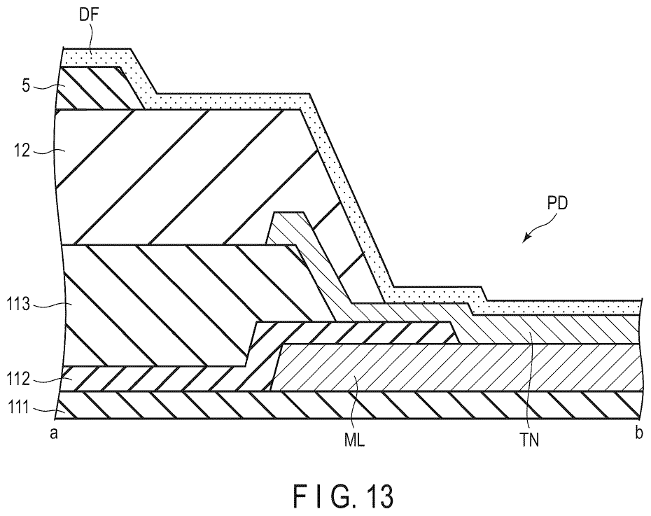

FIG. 13 is a cross-sectional view for explaining the state in which an evaporated film DF is formed in the pad PD shown in FIG. 12.

Here, the evaporated film DF is at least part of the organic layer OR1, upper electrode UE1, cap layer CP1 and sealing layer SE1 for forming the display element 201 explained with reference to FIG. 5. The evaporated film DF is formed on the rib 5, the insulating layer 12 and the terminal electrode TN.

This configuration example can prevent the local concentration of a stress at the interface between the conductive layers constituting the pad PD, the interface between a conductive layer and an insulating layer or the interface between insulating layers. Thus, the removal of the evaporated film DF from the pad PD can be prevented until the organic layer OR1, the upper electrode UE1, the cap layer CP1 and the sealing layer SE1 are removed by etching as explained with reference to FIG. 7.

Similar effects can be obtained in a case where the evaporated film DF is at least part of the organic layer OR2, upper electrode UE2, cap layer CP2 and sealing layer SE2 for forming the display element 202.

Moreover, similar effects can be obtained in a case where the evaporated film DF is at least part of the organic layer OR3, upper electrode UE3, cap layer CP3 and sealing layer SE3 for forming the display element 203.

Now, a comparative example is explained.

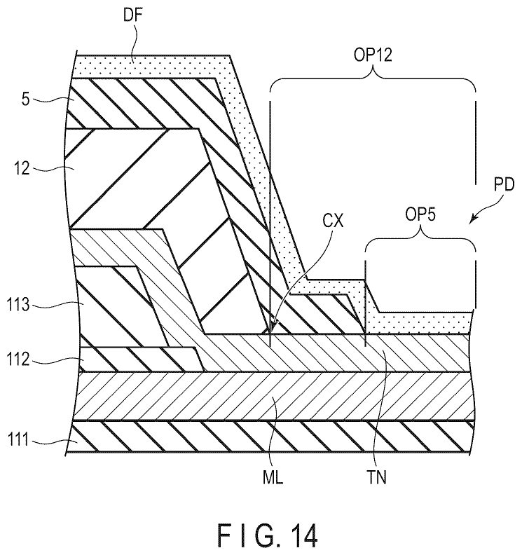

FIG. 14 is a cross-sectional view for explaining the state in which the evaporated film DF is formed in the pad PD according to a comparative example.

The comparative example shown in FIG. 14 is different from the above configuration example in respect that the aperture OP5 of the rib 5 is smaller than the aperture OP12 of the insulating layer 12. In other words, the rib 5 covers the insulating layer 12 and is in contact with the terminal electrode TN.

According to the analysis of the inventor, it is confirmed that a stress is concentrated in the portion CX in which the insulating layer 12, the rib 5 and the terminal electrode TN are in contact with each other in the comparative example shown in FIG. 14.

When the evaporated film DF is formed in the pad PD of this comparative example, the evaporated film DF easily rises from the rib 5 based on the portion CX in which a stress is concentrated. The evaporated film DF removed from the rib 5 floats inside the manufacturing device as foreign substances and could be a contaminant source. If the floating foreign substances are attached to the processing substrate, various defects could be caused.

As explained above, the embodiment can prevent the removal of the evaporated film DF from the pad PD. This configuration prevents the contamination of the manufacturing device and the generation of undesired foreign substances. In this manner, the reduction in reliability is prevented.

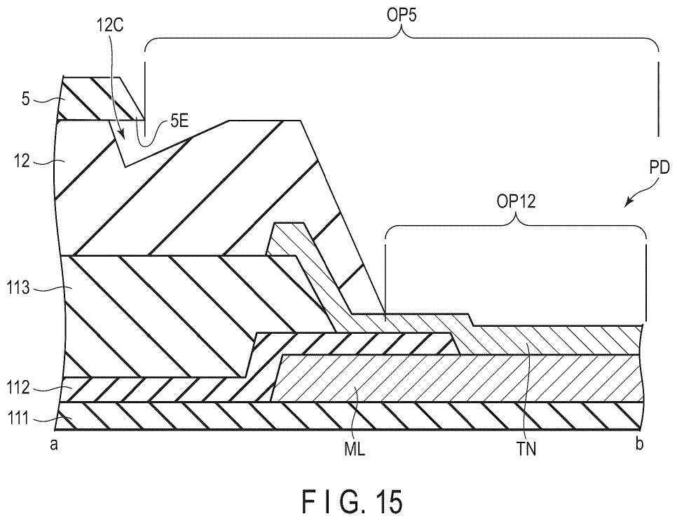

FIG. 15 is a cross-sectional view showing another configuration example of the pad PD along the a-b line of FIG. 11.

The configuration example shown in FIG. 15 is different from the configuration example shown in FIG. 12 in respect that the insulating layer 12 comprises a recess portion 12C on the upper surface which is in contact with the rib 5. The recess portion 12C is located outside the terminal electrode TN and the aperture OP12. Although not described in detail, the recess portion 12C is formed into a frame-like shape which surrounds the terminal electrode TN.

The rib 5 comprises a peripheral portion 5E along the aperture OP5. The peripheral portion 5E overlaps the recess portion 12C and is spaced apart from the insulating layer 12. In other words, the rib 5 is formed into an overhang shape. The peripheral portion 5E having the overhang shape is formed into a frame-like shape which surrounds the terminal electrode TN.

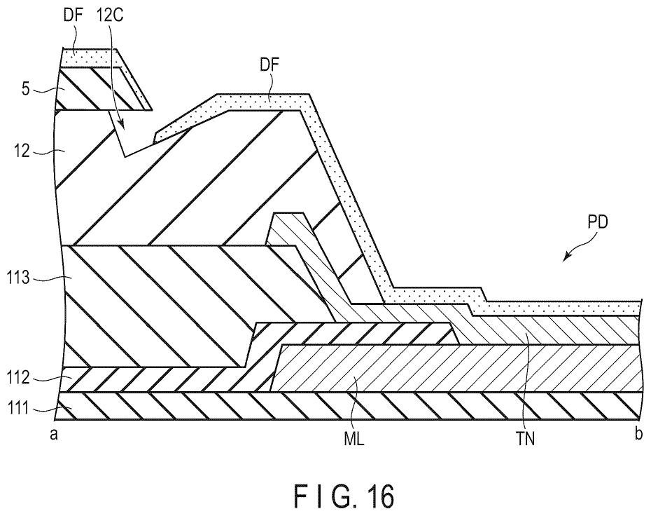

FIG. 16 is a cross-sectional view for explaining the state in which the evaporated film DF is formed in the pad PD shown in FIG. 15.

The evaporated film DF is formed on the rib 5 and is also formed on the insulating layer 12 and the terminal electrode TN. However, the evaporated film DF formed on the rib 5 is spaced apart from the evaporated film DF formed on the insulating layer 12. In other words, the evaporated film DF is divided by the rib 5 having an overhang shape. Thus, the evaporated film DF is segmentalized in the pad PD. By this configuration, the stress generated in the evaporated film DF is reduced.

In this configuration example, effects similar to those of the configuration example described above are obtained. In addition, as the evaporated film DF is segmentalized, the stress generated in the evaporated film DF is reduced, and further, the removal of the evaporated film DF from the pad PD is prevented.

Now, this specification explains a mother substrate 100 for a display device for manufacturing a plurality of display devices DSP in a lump.

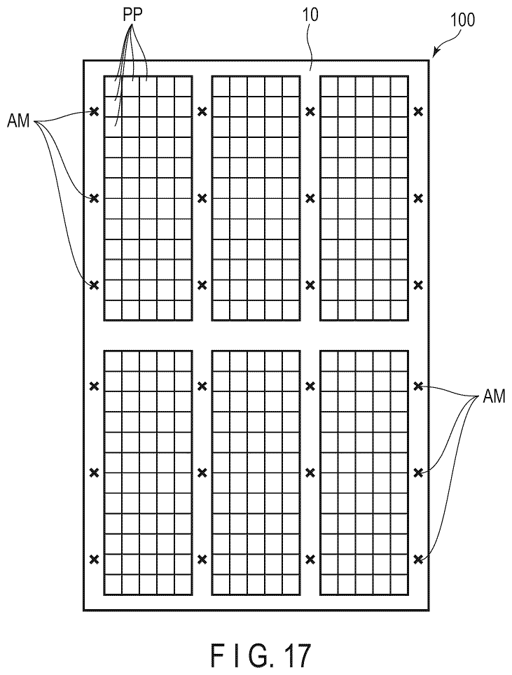

FIG. 17 is a plan view showing an example of the mother substrate 100.

The mother substrate 100 comprises a plurality of panel portions PP and alignment marks AM on the large substrate 10. The alignment marks AM are provided outside the panel portions PP.

Each panel portion PP which is extracted by dividing the mother substrate 100 along cut lines corresponds to the display panel PNL shown in FIG. 1. Thus, each of the panel portions PP comprises the display area DA and the surrounding area SA as shown in FIG. 1. Further, as shown in FIG. 3, each of the panel portions PP comprises the circuit layer 11, the insulating layer 12, the rib 5, the partition 6, the lower electrodes LE1, LE2 and LE3, the organic layers OR1, OR2 and OR3, the upper electrodes UE1, UE2 and UE3, the cap layers CP1, CP2 and CP3, the sealing layers SE1, SE2 and SE3, etc. Each of the panel portions PP comprises the pad PD in the surrounding area SA as shown in FIG. 11, etc. The circuit layer 11, the insulating layer 12 and the rib 5 are provided over the display area DA and the surrounding area SA in each panel portion PP.

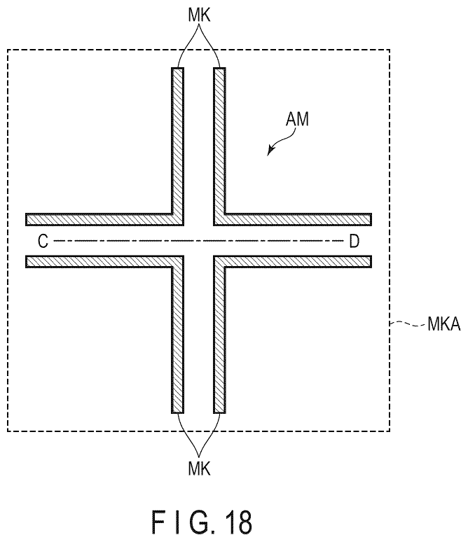

FIG. 18 is a plan view showing an example of the alignment mark AM shown in FIG. 17.

The alignment mark AM comprises four marks MK. Each of the marks MK is formed into an L-shape. These four marks MK are spaced apart from each other and form a cross-shaped space.

This specification explains a mark area MKA in which the alignment mark AM is provided.

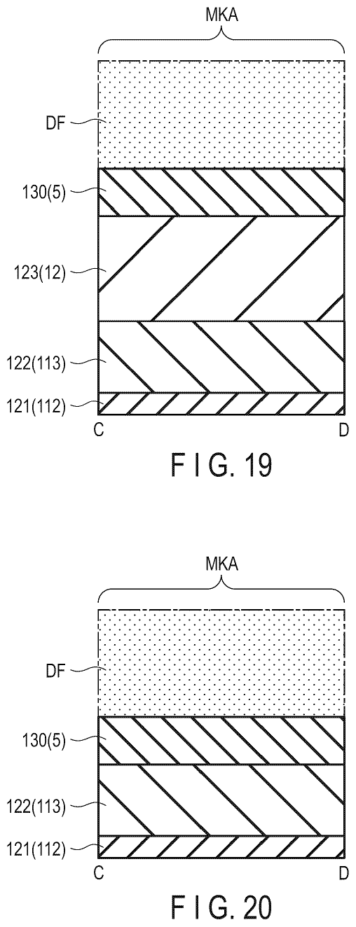

FIG. 19 is a cross-sectional view showing a configuration example of the mark area MKA along the C-D line of FIG. 18.

The mark area MKA comprises an inorganic insulating layer 130 as the top layer.

In the example shown in FIG. 19, an insulating layer 122 is provided on an insulating layer 121, and an insulating layer 123 is provided on the insulating layer 122, and the inorganic insulating layer 130 is provided on the insulating layer 123.

The insulating layer 121 is an insulating layer formed by the extension of the insulating layer 112 shown in FIG. 12.

The insulating layer 122 is an insulating layer formed by the extension of the insulating layer 113 shown in FIG. 12.

The insulating layer 123 is an insulating layer formed by the extension of the insulating layer 12 shown in FIG. 12.

The inorganic insulating layer 130 is an insulating layer formed by the extension of the rib 5 of the panel portion PP shown in FIG. 17. In other words, the top layer of the mark area MKA is formed of a material which is different from the materials of organic insulating layers such as the insulating layer 122 and the insulating layer 123.

The inorganic insulating layer 130 is formed of the same material as the rib 5 and is formed of, for example, silicon nitride, silicon oxide or silicon oxynitride.

When the evaporated film DF shown by one-dot chain lines is formed in this mark area MKA, the evaporated film DF is attached firmly to the inorganic insulating layer 130 compared to a case where the top layer is an organic insulating layer. Thus, the removal of the evaporated film DF from the mark area MKA can be prevented until the evaporated film DF is removed by etching.

In this manner, the reduction in reliability is prevented.

FIG. 20 is a cross-sectional view showing another configuration example of the mark area MKA along the C-D line of FIG. 18.

The configuration example shown in FIG. 20 is different from the configuration example shown in FIG. 19 in respect that the insulating layer 123 is omitted and the inorganic insulating layer 130 is provided on the insulating layer 122. The structure in which the top layer is the inorganic insulating layer 130 in the mark area MKA is the same as the configuration example described above.

In this configuration example, effects similar to those of the configuration example shown in FIG. 19 are obtained.

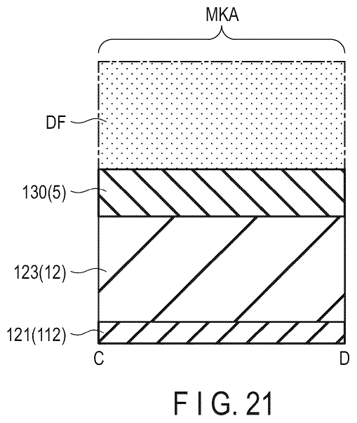

FIG. 21 is a cross-sectional view showing another configuration example of the mark area MKA along the C-D line of FIG. 18.

The configuration example shown in FIG. 21 is different from the configuration example shown in FIG. 19 in respect that the insulating layer 122 is omitted and the insulating layer 123 is provided on the insulating layer 121. The structure in which the top layer is the inorganic insulating layer 130 in the mark area MKA is the same as the configuration examples described above.

In this configuration example, effects similar to those of the configuration example shown in FIG. 19 are obtained.

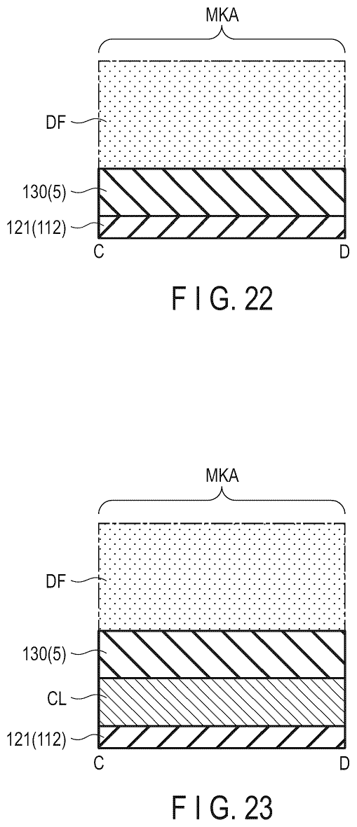

FIG. 22 is a cross-sectional view showing another configuration example of the mark area MKA along the C-D line of FIG. 18.

The configuration example shown in FIG. 22 is different from the configuration example shown in FIG. 19 in respect that the insulating layer 122 and the insulating layer 123 are omitted and the inorganic insulating layer 130 is provided on the insulating layer 121. The structure in which the top layer is the inorganic insulating layer 130 in the mark area MKA is the same as the configuration examples described above.

In this configuration example, effects similar to those of the configuration example shown in FIG. 19 are obtained.

FIG. 23 is a cross-sectional view showing another configuration example of the mark area MKA along the C-D line of FIG. 18.

The configuration example shown in FIG. 23 is different from the configuration example shown in FIG. 19 in respect that the insulating layer 122 and the insulating layer 123 are omitted and a conductive layer CL is provided between the inorganic insulating layer 130 and the insulating layer 121. The conductive layer CL is formed of the same material as the terminal electrode TN shown in FIG. 12. The structure in which the top layer is the inorganic insulating layer 130 in the mark area MKA is the same as the configuration examples described above.

In this configuration example, effects similar to those of the configuration example shown in FIG. 19 are obtained.

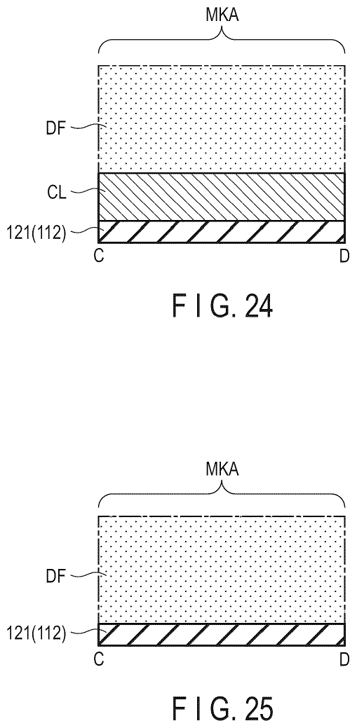

FIG. 24 is a cross-sectional view showing another configuration example of the mark area MKA along the C-D line of FIG. 18.

The configuration example shown in FIG. 24 is different from the configuration example shown in FIG. 19 in respect that the insulating layer 122, the insulating layer 123 and the inorganic insulating layer 130 are omitted and the conductive layer CL is provided on the insulating layer 121. In other words, the top layer in the mark area MKA is the conductive layer CL. The conductive layer CL is formed of the same material as the terminal electrode TN shown in FIG. 12.

When the evaporated film DF shown by one-dot chain lines is formed in this mark area MKA, the evaporated film DF is attached firmly to the conductive layer CL compared to a case where the top layer is an organic insulating layer. Thus, the removal of the evaporated film DF from the mark area MKA can be prevented until the evaporated film DF is removed by etching.

In this manner, the reduction in reliability is prevented.

FIG. 25 is a cross-sectional view showing another configuration example of the mark area MKA along the C-D line of FIG. 18.

The configuration example shown in FIG. 25 is different from the configuration example shown in FIG. 19 in respect that the insulating layer 122, the insulating layer 123 and the inorganic insulating layer 130 are omitted. In other words, the top layer in the mark area MKA is the insulating layer 121.

In this configuration example, effects similar to those of the configuration example shown in FIG. 19 are obtained.

As explained above, the embodiments can provide a display device and a mother substrate such that the reduction in reliability can be prevented.

All of the display devices and mother substrates that can be implemented by a person of ordinary skill in the art through arbitrary design changes to the display device and mother substrate described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
an organic insulating layer provided over a display area which displays an image and a surrounding area outside the display area above the substrate;
a lower electrode provided on the organic insulating layer in the display area;
a rib formed of an inorganic insulating material and overlapping a peripheral portion of the lower electrode;
a partition which comprises a lower portion provided on the rib and formed of a conductive material, and an upper portion provided on the lower portion and protruding from a side surface of the lower portion;
an organic layer provided on the lower electrode and including a light emitting layer;
an upper electrode which covers the organic layer and is in contact with the lower portion of the partition; and
a terminal electrode provided in the surrounding area, wherein
the organic insulating layer comprises a first aperture from which the terminal electrode is exposed,
the rib extends to the surrounding area and comprises a second aperture from which the terminal electrode is exposed,
the second aperture is larger than the first aperture in plan view, and
the organic insulating layer exposed from the rib between the first aperture and the second aperture has a frame-like shape.

2. The display device of claim 1, wherein
an edge of the terminal electrode is located outside the first aperture and is located inside the second aperture in plan view.

3. The display device of claim 1, wherein
the organic insulating layer is formed of polyimide.

4. The display device of claim 1, wherein
the rib is formed of one of silicon nitride, silicon oxide and silicon oxynitride.

5. The display device of claim 1, wherein
the terminal electrode is a multilayer body comprising a plurality of thin films formed of metal materials which are different from each other.

6. The display device of claim 1, wherein
the organic insulating layer comprises a recess portion,
the rib comprises a peripheral portion along the second aperture, and
the peripheral portion overlaps the recess portion and is spaced apart from the organic insulating layer.

7. A mother substrate for a display device, comprising:
a substrate;
a plurality of panel portions provided above the substrate; and
an alignment mark provided outside the panel portions above the substrate, wherein
each of the panel portions comprises:
an organic insulating layer provided over a display area which displays an image and a surrounding area outside the display area;
a lower electrode provided on the organic insulating layer in the display area;
a rib formed of an inorganic insulating material and overlapping a peripheral portion of the lower electrode;
a partition which comprises a lower portion provided on the rib and formed a conductive material, and an upper portion provided on the lower portion and protruding from a side surface of the lower portion;
an organic layer provided on the lower electrode and including a light emitting layer;
an upper electrode which covers the organic layer and is in contact with the lower portion of the partition; and
a terminal electrode provided in the surrounding area, and
a mark area in which the alignment mark is provided comprises a top layer formed of a material different from the organic insulating layer.

8. The mother substrate of claim 7, wherein
the top layer is an inorganic insulating layer formed of one of silicon nitride, silicon oxide and silicon oxynitride.

9. The mother substrate of claim 8, wherein
the inorganic insulating layer is formed of a same material as the rib.

10. The mother substrate of claim 7, wherein
the top layer is a conductive layer formed of a same material as the terminal electrode.

11. The mother substrate of claim 7, wherein
the organic insulating layer comprises a first aperture from which the terminal electrode is exposed,
the rib extends to the surrounding area and comprises a second aperture from which the terminal electrode is exposed,
the second aperture is larger than the first aperture in plan view, and
the organic insulating layer exposed from the rib between the first aperture and the second aperture has a frame-like shape.

12. The mother substrate of claim 11, wherein
an edge of the terminal electrode is located outside the first aperture and is located inside the second aperture in plan view.

13. The mother substrate of claim 11, wherein
the organic insulating layer is formed of polyimide.

14. The mother substrate of claim 11, wherein
the rib is formed of one of silicon nitride, silicon oxide and silicon oxynitride.

15. The mother substrate of claim 11, wherein
the terminal electrode is a multilayer body comprising a plurality of thin films formed of metal materials which are different from each other.

16. The mother substrate of claim 11, wherein
the organic insulating layer comprises a recess portion,
the rib comprises a peripheral portion along the second aperture, and
the peripheral portion overlaps the recess portion and is spaced apart from the organic insulating layer.

17. A display device comprising:
a substrate;
an organic insulating layer provided over a display area which displays an image and a surrounding area outside the display area above the substrate;
a lower electrode provided on the organic insulating layer in the display area;
a rib formed of an inorganic insulating material and overlapping a peripheral portion of the lower electrode;
a partition which comprises a lower portion provided on the rib and formed of a conductive material, and an upper portion provided on the lower portion and protruding from a side surface of the lower portion;
an organic layer provided on the lower electrode and including a light emitting layer;
an upper electrode which covers the organic layer and is in contact with the lower portion of the partition; and
a terminal electrode provided in the surrounding area, wherein
the organic insulating layer comprises a first aperture from which the terminal electrode is exposed and a recess portion located outside the first aperture,
the rib extends to the surrounding area and comprises a second aperture from which the terminal electrode is exposed, and
a peripheral portion along the second aperture of the rib overlaps the recess portion and is spaced apart from the organic insulating layer.

18. The display device of claim 17, wherein
an edge of the terminal electrode is located outside the first aperture and is located inside the recess portion.

19. The display device of claim 17, wherein
the organic insulating layer is formed of polyimide.

20. The display device of claim 17, wherein
the rib is formed of one of silicon nitride, silicon oxide and silicon oxynitride.
